(19) United States
(12) Patent Application Publication
(10) Pub. No.: US 2015/0083209 A1
(43) Pub. Date: Mar. 26, 2015

(54) COATABLE DIFFUSING AGENT COMPOSITION, METHOD FOR PRODUCING COATABLE DIFFUSING AGENT COMPOSITION, SOLAR CELL, AND METHOD FOR MANUFACTURING SOLAR CELL

(71) Applicants: NAGASE CHEMTEX CORPORATION, Osaka-shi, Osaka (JP); SHARP KABUSHIKI KAISHA, Osaka-shi, Osaka (JP)

(72) Inventors: Yosuke Ooi, Tatsuno-shi, Hyogo (JP); Daisuke Hironiwa, Osaka-shi (JP); Takahiro Hashimoto, Osaka-shi (JP); Yosuke Maruyama, Osaka-shi (JP)

(73) Assignees: NAGASE CHEMTEX CORPORATION, Osala-shi, Osaka (JP); SHARPP KABUSHIKI KAISHA, OSaka-shi, Osaka (JP)

(21) Appl. No.: 14/391,365

(22) PCT Filed: Mar. 27, 2013
(86) PCT No.: PCT/JP2013/058908

§ 371 Date: Oct. 8, 2014

(30) Foreign Application Priority Data
Apr. 13, 2012 (JP) 2012-091800

(51) Int. Cl. H01L 31/0216; H01L 31/18

(52) U.S. Cl. CPC H01L 31/02168; H01L 31/1804
USPC 136/256; 106/287.19; 438/72

(57) ABSTRACT

The present invention aims to provide a coatable diffusing agent composition that can prevent the formation of precipitates, has a longer solution life than conventional PTG solutions free of water, and thus can be stably stored for a long period of time even when this PTG solution is produced in large quantities, and is highly cost effective. The coatable diffusing agent composition of the present invention includes a titanate, a phosphorus compound, water, and an organic solvent.

### TECHNICAL FIELD

The present invention relates to a coatable diffusing agent composition intended to be used to diffuse dopants on silicon substrates, as well as a method for producing the coatable diffusing agent composition. The present invention further relates to a solar cell that has a pn junction and converts light energy into electric energy, as well as a method for producing the solar cell.

### BACKGROUND ART

Crystalline silicon solar cells use a pn junction to convert light energy into electric energy. The pn junction in a crystalline silicon solar cell generally includes a p-type semiconductor prepared by diffusing boron as a dopant on a silicon substrate, and an n-type semiconductor prepared by diffusing phosphorus as a dopant on a silicon substrate. The pn junction may be formed by diffusing a p-type dopant (e.g. boron) in an n-type semiconductor silicon substrate, or alternatively by diffusing an n-type dopant (e.g. phosphorus) in a p-type semiconductor silicon substrate.

The technique of diffusing phosphorus may also be employed to impart some properties to solar cells.

Known methods for diffusing dopants include an ion implantation method and a thermal diffusion method. In particular, the thermal diffusion method is highly cost effective.

In the thermal diffusion method, a film made of a diffusing agent containing a dopant is formed on a silicon substrate and heated to a high temperature to diffuse the dopant. The diffusing agent film is formed in many cases by application or chemical vapor deposition (CVD). For the application of the diffusing agent, many methods such as spin coating, spray coating, and printing can be employed.

In order to produce a solar cell by thermally diffusing phosphorus in a silicon substrate to form a pn junction, the following process may be employed, for example. A coatable diffusing agent containing phosphorus is first applied to a p-type silicon substrate and fired at 800° C. to 1100° C. to thermally diffuse the phosphorus. Thereafter, the coatable diffusing agent containing phosphorus is removed with an aqueous solution of hydrofluoric acid. This results in the formation of a pn junction.

Furthermore, for higher light conversion efficiency, solar cells may be configured to include an antireflection film on a pn junction layer to more easily absorb light. In this case, silicon nitride films, titanium oxide films and the like are often used as the antireflection film.

A phospho titanate glass (PTG) film includes diphosphorus pentaoxide and titanium oxide. The PTG film serves as both a phosphorus-diffusing agent and an antireflection film in the process of producing a solar cell. For example, an n-type diffusion layer and an antireflection film can be simultaneously formed by heating a coating film of a PTG solution formed on a silicon substrate. Thus, methods for producing a solar cell including the step of forming a PTG film are very highly cost effective and therefore have been often employed (see Patent Literatures 1 to 5, for example).

The PTG film may be formed by applying a coatable diffusing agent composition (PTG solution) containing titanium to a silicon substrate by any application method and then firing it at 800° C. to 1100° C. to form an n-type diffusion layer and an antireflection film (PTG film). The PTG film can also be formed by a CVD method.

The composition of the PTG solution may include, for example, a titanate, carboxylic acid, diphosphorus pentaoxide, and an alcohol, as taught in Patent Literature 2.

### CITATION LIST

### Patent Literature

Patent Literature 1: JP S59-115524 A
Patent Literature 2: JP H07-22634 A
Patent Literature 3: JP H08-85874 A
Patent Literature 4: JP 2000-309869 A
Patent Literature 5: JP 2010-109201 A

### SUMMARY OF INVENTION

### Technical Problem

Conventional PTG solutions tend to allow the titanate to be hydrolyzed by a hydroxy group contained in the solutions to cause decomposition and condensation of the titanium component and the phosphorus component. Moreover, as the hydrolysis reaction proceeds, the titanium component forms precipitates of titanium hydroxide, which is insoluble in alcohol solvents, thus significantly deteriorating the performance of the PTG solution as a coating agent.

Because of such tendencies, the PTG solutions are difficult to stably store for a long period of time when they are industrially produced in large quantities. The solutions therefore need to be produced in small quantities at frequent intervals, which is disadvantageous in cost.

### Solution to Problem

As a result of intensive studies for solving the above problems, the present inventors have found that the addition of water to a coatable diffusing agent composition containing a titanate, a phosphorus compound, and an organic solvent (this composition corresponds to a PTG solution) prevents the formation of precipitates (titanium hydroxide), gives a solution life longer than that of conventional PTG solutions free of water, and thus allows stable, long-term storage of the PTG solution even when the PTG solution is produced in large quantities, and makes the PTG solution highly cost effective. Thus, the present invention has been completed.

The inventors also have found that a PTG solution in which precipitates (titanium hydroxide) are even less likely to be formed can be obtained by performing the addition of water after mixing the organic solvent and the phosphorus compound.

Accordingly, the coatable diffusing agent composition of the present invention includes: a titanate; a phosphorus compound; water; and an organic solvent.

In the coatable diffusing agent composition, the phosphorus compound is preferably a diphosphorus pentaoxide and/or a phosphate. The organic solvent is preferably an alcohol.

In the coatable diffusing agent composition, the water is preferably present at a concentration of 5% by weight or less, more preferably 0.05 to 1.5% by weight.

The coatable diffusing agent composition preferably has a weight ratio of titanium atoms to phosphorus atoms, represented by Ti/P, of 0.5 to 0.9.

The method for producing a coatable diffusing agent composition of the present invention is a method for producing the coatable diffusing agent composition, which includes mixing a titanate with a solution (A) that contains an organic solvent, a phosphorus compound, and water.

In the method for producing the coatable diffusing agent composition, the solution (A) is preferably prepared by mixing water with a solution (B) that contains the organic solvent and the phosphorus compound.

In the method for producing the coatable diffusing agent composition, the water is preferably pure water.

The solar cell of the present invention includes an n-type diffusion layer and an antireflection film each formed from the coatable diffusing agent composition of the present invention.

The method for producing a solar cell of the present invention includes: applying the coatable diffusing agent composition of the present invention to a silicon substrate; and subsequently heat treating the composition to form an n-type diffusion layer and an antireflection film on the silicon substrate.

### Advantageous Effects of Invention

Since the coatable diffusing agent composition of the present invention contains water in addition to a titanate, a phosphorus compound, and an organic solvent, it can prevent the formation of precipitates (titanium hydroxide) for a long period of time, has a long solution life, and thus can be stably stored for a long period of time even when the coatable diffusing agent composition is produced in large quantities, and is highly cost effective. The coatable diffusing agent composition of the present invention can also be evenly and uniformly applied to a silicon substrate.

In the method for producing the coatable diffusing agent composition of the present invention, the components are added in a specific order. This allows to suitably produce the coatable diffusing agent composition having the above-described properties.

In the solar cell of the present invention, since an n-type diffusion layer and an antireflection film are prepared from the coatable diffusing agent composition of the present invention, the n-type diffusion layer and the antireflection film are each uniform. The solar cell of the present invention is also inexpensive as compared with conventional solar cells.

In the method for producing a solar cell of the present invention, the coatable diffusing agent composition of the present invention is used as a diffusing agent. This allows to suitably produce a solar cell having the above-described properties.

### BRIEF DESCRIPTION OF DRAWINGS

FIG. 1(a) is a schematic cross-sectional view showing an example of the solar cell of the present invention, whereas FIG. 1(b) is a schematic cross-sectional view showing another example of the solar cell of the present invention.

FIG. 2-1(a) to 2-1(d) are cross-sectional views to illustrate the method for producing a solar cell of the present invention.

FIG. 2-2(e) to 2-2(g) are cross-sectional views to illustrate the method for producing a solar cell of the present invention.

FIG. 3 is a graph plotting the relation between the concentration of water (2) and the time during which the solution (coatable diffusing agent composition) remained transparent in Comparative Example 1 and Examples 1 to 9.

FIG. 4 is a graph plotting the relation between Ti/P weight ratio and the time during which the solution (coatable diffusing agent composition) remained transparent in Example 3 and Examples 10 to 13.

FIG. 5 is a graph plotting the relation between the compositional weight of water (1) and the time during which the solution (coatable diffusing agent composition) remained transparent in Example 3 and Examples 14 to 18.

### DESCRIPTION OF EMBODIMENTS

The coatable diffusing agent composition of the present invention will first be described.

The coatable diffusing agent composition of the present invention contains a titanate, a phosphorus compound, water, and an organic solvent.

Examples of the titanates include tetramethoxytitanium, tetraethoxytitanium, tetrapropoxytitanium, tetraisopropoxytitanium, tetrabutoxytitanium, tetra-2-ethylhexyltitanium, and multimers of these titanium alkoxides, titanium chelates, and titanium acylates. These may be used alone or in combination of two or more.

Preferred among these is tetraisopropoxytitanium because it is widely available in large quantities and advantageous in terms of cost.

In the coatable diffusing agent composition, the titanate is preferably present at a concentration of 20% by weight or less, more preferably 10% by weight or less.

This is because if the concentration of the titanate is more than 20% by weight, the coatable diffusing agent composition has a high solids content and thus may have deteriorated coating properties.

The preferred lower limit of the concentration of the titanate is 0.5% by weight.

Examples of the phosphorus compounds include diphosphorus pentaoxide, phosphoric acid, and phosphates.

These phosphorus compounds may be used alone or in combination of two or more.

Preferred among these are diphosphorus pentaoxide and phosphates that have a small number of OH groups which may cause the hydrolysis reaction.

Examples of the phosphates include methyl phosphate, dimethyl phosphate, trimethyl phosphate, ethyl phosphate, diethyl phosphate, triethyl phosphate, propyl phosphate, dipropyl phosphate, tripropyl phosphate, isopropyl phosphate, diisopropyl phosphate, butyl phosphate, dibutyl phosphate, tributyl phosphate, and multimers of these phosphates. These phosphates may be used alone or in combination of two or more.

These phosphorus compounds may be present as the phosphorus compounds themselves or in the form of reaction products with an organic solvent or other components in the coatable diffusing agent composition.

In the coatable diffusing agent composition, the phosphorus compound is preferably present at a concentration of 20% by weight or less, more preferably 10% by weight or less.

This is because if the concentration of the phosphorus compound is more than 20% by weight, the coatable diffusing agent composition has a high solids content and thus may have deteriorated coating properties.

The preferred lower limit of the concentration of the phosphorus compound is 0.5% by weight.

Examples of the organic solvents include alcohols, organic acids, organic esters, organic amides, and ethers, with alcohols being suitable. In particular, most suitable are alcohols corresponding to those produced through the hydrolysis of the alkoxy group of the titanate described above.

This is because such an alcohol shifts the chemical equilibrium to reduce the likelihood of hydrolysis of the titanate, which is expected to allow stable storage for a long period of time.

Thus, for example, when tetraisopropoxytitanium is used as the titanate, the organic solvent is desirably isopropanol.

The organic solvent is preferably present at a concentration of 60% by weight or more, more preferably 80% by weight or more, in the coatable diffusing agent composition.

This is because if the concentration of the organic solvent is less than 60% by weight, the coatable diffusing agent composition has a high solids content and thus may have deteriorated coating properties.

The preferred upper limit of the concentration of the organic solvent is 99% by weight.

As for the proportions of the titanate and the phosphorus compound, the weight proportion of titanium atoms to phosphorus atoms is preferably 0.2-2.0:1. That is, the weight ratio of titanium atoms to phosphorus atoms (titanium/phosphorus) is preferably 0.2 to 2.0.

When the weight ratio of titanium atoms to phosphorus atoms (titanium/phosphorus) is within the range mentioned above, the performance as an antireflection film and the phosphorus-diffusing performance of a PTG film formed from the coatable diffusing agent composition both fall within ranges suitable for use in solar cell production processes. Such a PTG film is suitable as a PTG film for producing a solar cell.

The weight ratio of titanium atoms to phosphorus atoms (titanium/phosphorus) is more preferably 0.5 to 0.9, and even more preferably 0.67 to 0.75.

If the proportion of the titanate is high (or if the weight ratio (titanium/phosphorus) is large), the resulting PTG film has a high refraction index and therefore will serve as an excellent antireflection film; however, since the concentration (proportion) of phosphorus is low, the desired diffusion of phosphorus tends to be difficult. Conversely, if the proportion of the titanate is low (or if the weight ratio (titanium/phosphorus) is small), phosphorus can be easily diffused; however, the refraction index of the PTG film deviates from the optimum value and the PTG film thus tends to be less effective as an antireflection film.

The coatable diffusing agent composition of the present invention contains water.

It is very important for the coatable diffusing agent composition to contain water. Water greatly improves long-term storage stability of the coatable diffusing agent composition.

The water is preferably present at a concentration of 5% by weight or less, more preferably 1.5% by weight or less, in the coatable diffusing agent composition.

If the water is added at a concentration of more than 5% by weight, the titanate may be rapidly hydrolyzed to form white precipitates of titanium hydroxide in a large amount. Further, these precipitates can bind to the phosphorus component in the solution and thereby markedly reduce the phosphorus concentration in the solution. Therefore, the solution (composition) in which the precipitates are formed cannot be used as a coatable diffusing agent.

The concentration of water is also desirably 0.05% by weight or more to produce the effects of the present invention.

The coatable diffusing agent composition may further contain a surfactant.

Examples of the surfactants include nonionic surfactants and ionic surfactants.

The coatable diffusing agent composition having such a composition can be suitably produced by the method for producing a coatable diffusing agent composition according to the present invention.

The method for producing a coatable diffusing agent composition of the present invention will next be described.

The method for producing a coatable diffusing agent composition of the present invention is a method for producing the coatable diffusing agent composition described above and includes mixing a titanate with a solution (A) that contains an organic solvent, a phosphorus compound, and water.

In the production method, it is important to prepare the solution (A) that contains an organic solvent, a phosphorus compound, and water and then mix a titanate with the solution (A).

This is because such a step can prevent the formation of precipitates caused by hydrolysis of the titanate.

In the production method, the solution (A) may be prepared by simultaneously mixing an organic solvent, a phosphorus compound, and water. Preferably, the solution (A) is prepared by preliminarily preparing a solution (B) that contains an organic solvent and a phosphorus compound and then mixing water with the solution (B).

This is because such a preparation method can prevent the formation of precipitates caused by hydrolysis of the titanate.

The water may be incorporated all at once or in several portions. For example, after part of the water is mixed with an organic solvent and a phosphorus compound, the rest of the water may be incorporated. Preferably, an organic solvent and a phosphorus compound are preliminarily mixed to dissolve the phosphorus compound in the organic solvent before the whole amount of water is incorporated.

The water is preferably added as pure water although it may be added in the form of an aqueous solution of an inorganic acid, an organic acid, an inorganic alkali, an organic alkali, or the like.

The pure water herein means water substantially free of components other than water.

A particularly preferred embodiment of the method for producing a coatable diffusing agent composition of the present invention is described as follows.

First, 80% by weight or more of isopropyl alcohol and 10% by weight or less of diphosphorus pentaoxide based on the total weight of the composition to be produced are charged and mixed to form a solution. Subsequently, 0.05 to 1.5% by weight of water is added, and the resultant mixture is well stirred. Thereafter, 10% by weight or less of tetraisopropoxytitanium is added to the mixture to prepare a coatable diffusing agent composition.

The coatable diffusing agent composition of the present invention may be produced by such a method for producing a coatable diffusing agent composition.

The solar cell of the present invention will next be described.

The solar cell of the present invention includes an n-type diffusion layer and an antireflection film each formed from the coatable diffusing agent composition of the present invention.

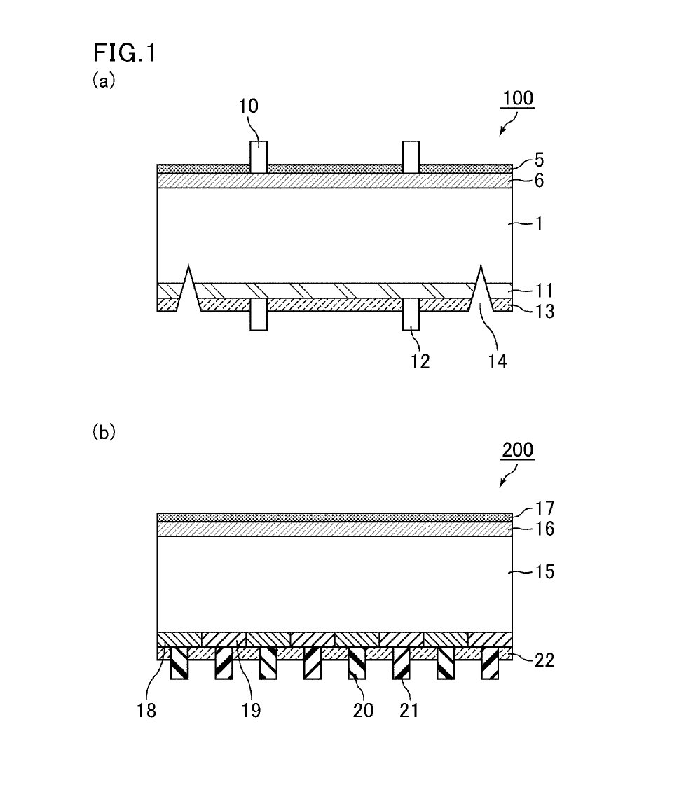

Specific examples of such solar cells include solar cells having the structures shown in FIG. 1.

FIG. 1(a) is a schematic cross-sectional view showing one example of the solar cell of the present invention. FIG. 1(b) is a schematic cross-sectional view showing another example of the solar cell of the present invention.

FIG. 1(a) shows a solar cell 100 which is a double-sided contact solar cell and includes a textured structure with fine pyramidal structures (not shown) on one surface (a light-receiving surface, the upper surface as viewed in the figure) of a silicon substrate 1. The solar cell 100 further includes on the structure an n-type diffusion layer 6 and an antireflection film 5 made of titanium oxide containing phosphorus. On this light-receiving surface side, light-receiving surface electrodes 10 are provided which pass through the antireflection film 5 and are connected to the n-type diffusion layer 6.

On the other surface (a back surface, the lower surface as viewed in the figure) of the silicon substrate 1, a back surface field (BSF) layer 11 is provided as well as a back aluminum electrode 13 and back silver electrodes 12. Further, grooves 14 for pn junction isolation are provided on the back surface.

FIG. 1(b) shows a solar cell 200 which is a back contact solar cell and includes a textured structure with fine pyramidal structures (not shown) on one surface (a light-receiving surface, the upper surface as viewed in the figure) of a silicon substrate 15. The solar cell 200 further includes on the structure a light-receiving surface n-type diffusion layer 16 and an antireflection film 17 made of titanium oxide containing phosphorus.

On the other surface (a back surface, the lower surface as viewed in the figure) of the silicon substrate 15, n-type diffusion layers 18 and p-type diffusion layers 19 are provided. Further, a back passivation film 22 is stacked on these layers. Further, n-type electrodes 20 and p-type electrodes 21 are provided such that they pass through the back passivation film 22 and are each connected, in the case of the n-type electrodes 20, to the n-type diffusion layer 18 and, in the case of the p-type electrodes 21, to the p-type diffusion layer 19.

It should be noted that the structure of the solar cell of the present invention is not limited to those shown in FIGS. 1(a) and 1(b), and any structure can be used as long as it includes an n-type diffusion layer and an antireflection film made of titanium oxide containing phosphorus.

The method for producing a solar cell of the present invention will next be described.

The method for producing a solar cell of the present invention includes applying the coatable diffusing agent composition of the present invention to a silicon substrate, and subsequently heat treating the composition to form an n-type diffusion layer and an antireflection film on the silicon substrate.

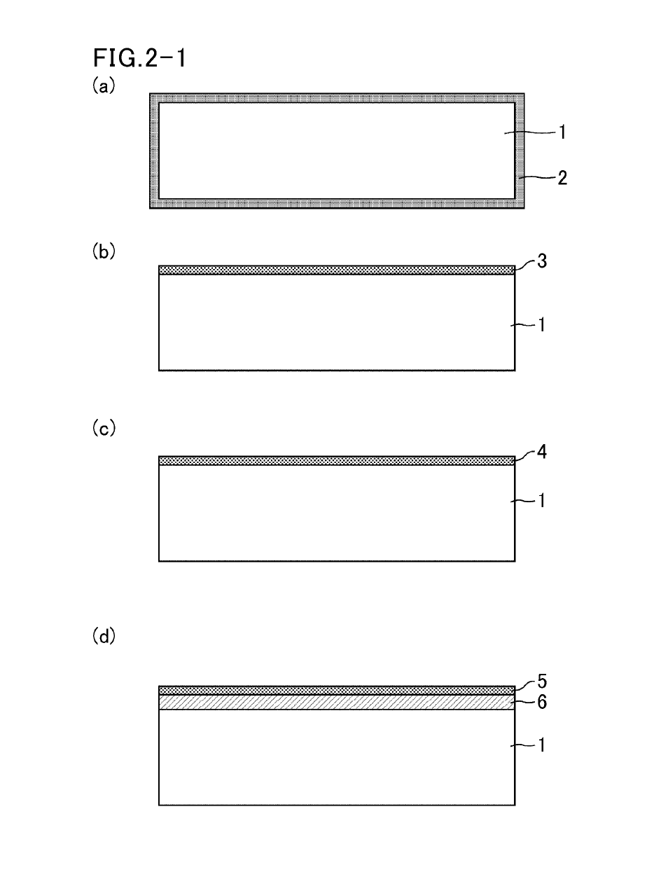

In the following, as an example of the above method for producing a solar cell, the method for producing the double-sided contact solar cell shown in FIG. 1(a) is described in order of steps with reference to FIG. 2.

FIGS. 2-1(a) to 2-1(d) and FIGS. 2-2(e) to 2-2(g) are cross-sectional views to illustrate the method for producing a solar cell of the present invention.

Each of FIGS. 2-1(a) to 2-1(d) and FIGS. 2-2(e) to 2-2(g) shows a cross section of a solar cell. The upper surface as viewed in each figure is a light-receiving surface, and the opposite surface is a back surface.

(1) First, a silicon substrate 1 is prepared by slicing, with a known wire saw or the like, a monocrystalline or polycrystalline silicon ingot having n-type conductivity or p-type conductivity. Since the silicon substrate 1 immediately after slicing has a slice damage layer 2 produced during the slicing operation (see FIG. 2-1(a)), the slice damage layer 2 is removed using a mixed acid of an aqueous hydrogen fluoride solution and nitric acid, for example.

(2) Next, one surface (a light-receiving surface) of the silicon substrate 1 is etched with an aqueous NaOH solution or the like to form fine pyramidal projections and recesses (textured structure) 3 (see FIG. 2-1(b)). This textured structure 3 contributes to light confinement at the light-receiving surface of solar cells and is effective for improving the properties of solar cells. The etching may be performed with an acid.

The textured structure 3 is omitted in FIGS. 2-1(c) to 2-2(g) referred to in the descriptions below.

(3) Next, a coatable diffusing agent composition 4 is applied to the light-receiving surface of the silicon substrate 1 (see FIG. 2-1(c)).

The application may be performed by a spin coating method or other methods.

(4) Next, the silicon substrate 1 with the coatable diffusing agent composition 4 applied thereto is placed in a quartz tube furnace and heat treated under N₂ atmosphere at 800° C. to 1100° C. for 5 to 30 minutes.

This allows phosphorus to diffuse on the light-receiving surface (the upper surface as viewed in the figure) of the silicon substrate 1, resulting in the formation of an n-type diffusion layer 6 as well as an antireflection film 5 made of titanium oxide containing phosphorus (see FIG. 2-1(d)).

(5) Next, an aluminum paste 8 and a silver paste 9 are printed on the back surface (the lower surface as viewed in the figure) of the silicon substrate 1 by a screen printing method and then dried. Thereafter, a silver paste 7 is printed on the antireflection film 5 on the light-receiving surface of the silicon substrate 1 by a screen printing method and then dried (see FIG. 2-2(e)).

(6) Next, the silicon substrate 1 obtained after step (5) is fired at 800° C. to 1100° C. This allows the silver paste 7 on the antireflection film 5 on the light-receiving surface to pass through the antireflection film 5 and be connected to the n-type diffusion layer 6 to form light-receiving surface electrodes 10, and at the same time allows part of the aluminum paste 8 on the back surface to diffuse in the silicon substrate 1 to form a BSF layer 11, as well as allowing back aluminum electrodes 13 and back silver electrodes 12 to be formed (see FIG. 2-2(f)).

(7) Finally, grooves 14 are formed in the periphery of the back surface of the silicon substrate 1 by laser treatment to achieve pn junction isolation (see FIG. 2-2(g)).

These steps produce a solar cell.

It is to be noted that the method for producing a solar cell of the present invention is not limited to the above method described with reference to FIGS. 2-1 and 2-2, and any method can be used as long as it includes using the coatable diffusing agent composition of the present invention to form an n-type diffusion layer and an antireflection film made of titanium oxide containing phosphorus.

### EXAMPLES

The present invention is described below by reference to, but not limited only to, examples.

In the examples and comparative examples below, the organic solvent, the titanate, and the phosphorus compound used were isopropyl alcohol, tetraisopropoxytitanium, and diphosphorus pentaoxide, respectively.

In the examples and the comparative examples, the term “water” when used alone refers to pure water substantially free of components other than water.

### Examples 1 to 18, Comparative Example 1

Isopropyl alcohol (isopropanol), diphosphorus pentaoxide, and water (1) were first mixed to form a solution. Then, water (2) was further added and mixed, and tetraisopropoxytitanium was then mixed with the mixture, thus providing a coatable diffusing agent composition.

The amounts of the components used in the examples are shown in Table 1. The concentration of water and the timing of adding water in the examples were adjusted by varying the amounts of water (1) and water (2).

### (Evaluation of Stability Over Time)

The coatable diffusing agent compositions obtained in the examples were stored under high temperature conditions of 60° C., and then the time until precipitates (titanium hydroxide) were formed was evaluated. The results are shown in Table 1.

The time until precipitates were formed was evaluated based on the time during which the solution (coatable diffusing agent composition) remained transparent.

Since storage of the coatable diffusing agent compositions at a higher temperature tends to lead to more rapid formation of precipitates, this evaluation shows the stability over time of the coatable diffusing agent compositions when they are industrially produced in large quantities, in terms of precipitate formation.

TABLE 1

| | | | | | | | Evaluation results of storage test | |
|---|---|---|---|---|---|---|---|---|
| | | | | | | | | Time during |
| | Compositional weight (g) | | | | | Ti/P | Storage | which |
| | | Diphosphorus | | | | weight | temperature | solution remained |
| | Isopropanol | pentaoxide | Water (1) | Water (2) | Tetraisopropoxytitanium | ratio | (° C.) | transparent (h) |
| Example 1 | 90 | 3.1 | 0.00 | 0.05 | 5.6 | 0.70 | 60 | 18 |
| Example 2 | 90 | 3.1 | 0.00 | 0.10 | 5.6 | 0.70 | 60 | 33 |
| Example 3 | 90 | 3.1 | 0.00 | 0.15 | 5.6 | 0.70 | 60 | 39 |
| Example 4 | 90 | 3.1 | 0.00 | 0.20 | 5.6 | 0.70 | 60 | 42 |
| Example 5 | 90 | 3.1 | 0.00 | 0.30 | 5.6 | 0.70 | 60 | 39 |
| Example 6 | 90 | 3.1 | 0.00 | 0.45 | 5.6 | 0.70 | 60 | 36 |
| Example 7 | 90 | 3.1 | 0.00 | 0.90 | 5.6 | 0.70 | 60 | 27 |
| Example 8 | 90 | 3.1 | 0.00 | 1.50 | 5.6 | 0.70 | 60 | 24 |
| Example 9 | 90 | 3.1 | 0.00 | 3.00 | 5.6 | 0.70 | 60 | 30 |
| Example 10 | 90 | 3.1 | 0.00 | 0.15 | 5.2 | 0.65 | 60 | 30 |
| Example 11 | 90 | 3.1 | 0.00 | 0.15 | 5.4 | 0.67 | 60 | 36 |
| Example 12 | 90 | 3.1 | 0.00 | 0.15 | 5.8 | 0.72 | 60 | 39 |
| Example 13 | 90 | 3.1 | 0.00 | 0.15 | 6.0 | 0.75 | 60 | 36 |
| Example 14 | 90 | 3.1 | 0.15 | 0.15 | 5.6 | 0.70 | 60 | 36 |
| Example 15 | 90 | 3.1 | 0.30 | 0.15 | 5.6 | 0.70 | 60 | 36 |
| Example 16 | 90 | 3.1 | 0.45 | 0.15 | 5.6 | 0.70 | 60 | 30 |
| Example 17 | 90 | 3.1 | 0.90 | 0.15 | 5.6 | 0.70 | 60 | 24 |
| Example 18 | 90 | 3.1 | 1.50 | 0.15 | 5.6 | 0.70 | 60 | 21 |
| Comparative | 90 | 3.1 | 0.00 | 0.00 | 5.6 | 0.70 | 60 | 15 |
| Example 1 | | | | | | | | |

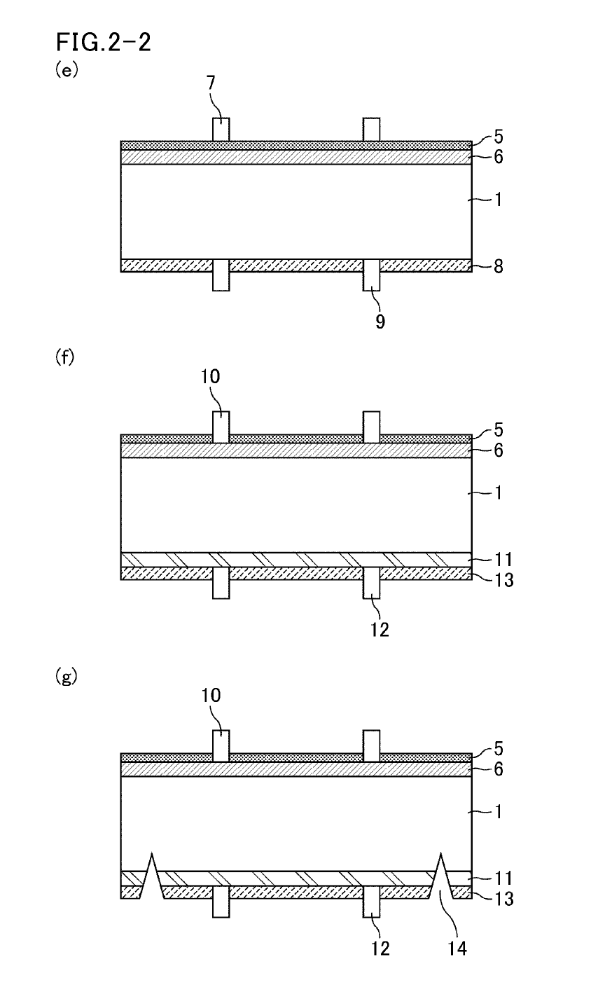

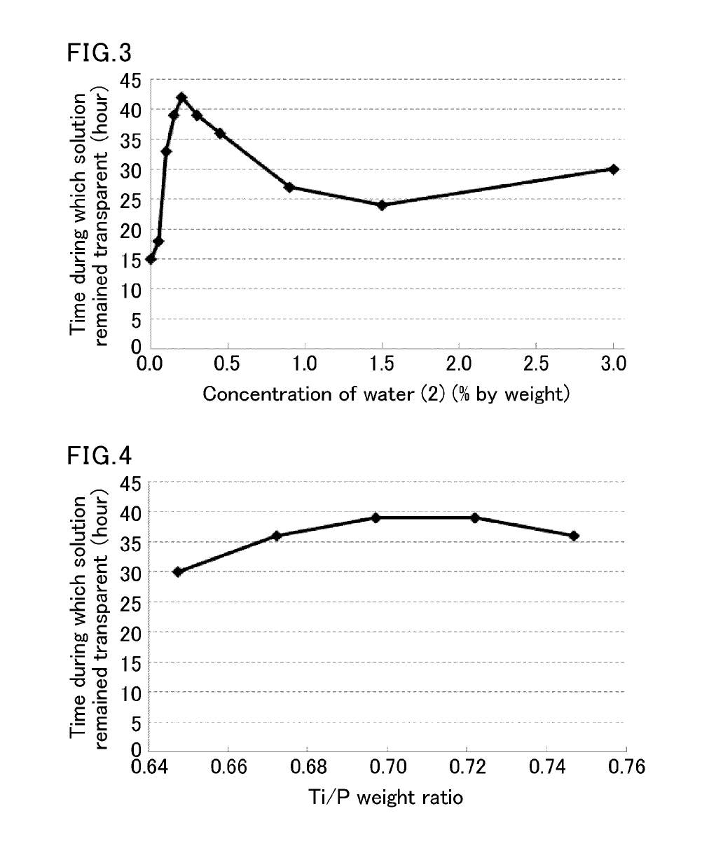

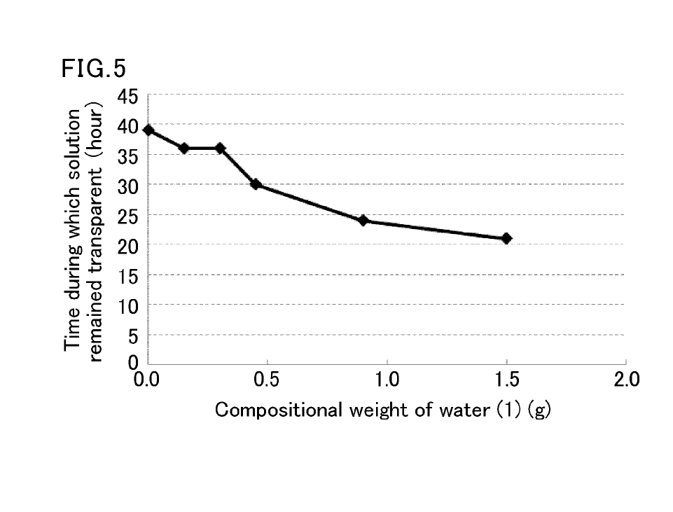

On the basis of the results shown in Table 1, the relation between the concentration of water (2) and the time during which the solution (coatable diffusing agent composition) remained transparent in Comparative Example 1 and Examples 1 to 9 is plotted in FIG. 3; the relation between the Ti/P weight ratio and the time during which the solution (coatable diffusing agent composition) remained transparent in Example 3 and Examples 10 to 13 is plotted in FIG. 4; and the relation between the compositional weight of water (1) and the time during which the solution (coatable diffusing agent composition) remained transparent in Example 3 and Examples 14 to 18 is plotted in FIG. 5.

The results in FIG. 3 show that the time during which the solution (coatable diffusing agent composition) was transparent with no precipitate formation and no suspension was longest in Example 4. Comparison between Example 4, in which the time during which the solution was transparent was maximal, and Comparative Example 1 shows that the composition of Example 4 had a solution life about 2.5 times longer than that of Comparative Example 1. This indicates that the addition of water (2) is very effective for improving stability of the coatable diffusing agent composition.

FIG. 4 shows that the time during which the solution (coatable diffusing agent composition) was transparent was maximal at a weight ratio (titanium/phosphorus) of around 0.70 to 0.72.

This reveals that the coatable diffusing agent composition with a weight ratio (titanium/phosphorus) of around these values has the best solution life in terms of precipitate formation.

FIG. 5 demonstrates that even when water is added at the timing of water (2), the time during which the coatable diffusing agent composition is transparent tends to be reduced if water is added at the timing of water (1).

### Examples 19 to 22, Comparative Examples 2 to 5

Coatable diffusing agent compositions were prepared in the same manner as in Example 3 or Comparative Example 1. The coatable diffusing agent compositions were evaluated for stability over time when they were stored under temperature conditions of 40° C., 25° C., 5° C., or −5° C. The results are shown in Table 2. The evaluation of stability over time was performed in the same manner as in Examples 1 to 18 and Comparative Example 1, except for the storage temperature.

TABLE 2

| | | | | | | Evaluation results of storage | |
|---|---|---|---|---|---|---|---|
| | | | | | | test | |
| | Compositional weight (g) | | | | Ti/P | Storage | Time during which |
| | | Diphosphorus | | | weight | temperature | solution remained |
| | Isopropanol | pentaoxide | Water (2) | tetraisopropoxytitanium | ratio | (° C.) | transparent (h) |
| Example 19 | 90 | 3.1 | 0.15 | 5.6 | 0.70 | 40 | 960 |
| Example 20 | 90 | 3.1 | 0.15 | 5.6 | 0.70 | 25 | 2500 |
| Example 21 | 90 | 3.1 | 0.15 | 5.6 | 0.70 | 5 | >4300 |
| Example 22 | 90 | 3.1 | 0.15 | 5.6 | 0.70 | −5 | >4300 |
| Comparative | 90 | 3.1 | 0.00 | 5.6 | 0.70 | 40 | 240 |
| Example 2 | | | | | | | |
| Comparative | 90 | 3.1 | 0.00 | 5.6 | 0.70 | 25 | 1050 |
| Example 3 | | | | | | | |
| Comparative | 90 | 3.1 | 0.00 | 5.6 | 0.70 | 5 | 2900 |
| Example 4 | | | | | | | |
| Comparative | 90 | 3.1 | 0.00 | 5.6 | 0.70 | −5 | 2900 |
| Example 5 | | | | | | | |

The results in Table 2 show that, at any of the above storage temperatures, there was an about 1.5-fold or greater difference in the time during which the solution was transparent between the coatable diffusing agent compositions in which the compositional weight of water (2) was 0.15 g and those free of water.

This demonstrates that the coatable diffusing agent composition of the present invention shows improved stability over time in terms of precipitate formation, even over a practical storage temperature range.

### Examples 23 to 29

Coatable diffusing agent compositions were prepared in the same manner as in Example 19, except that an aqueous solution of an inorganic acid, an organic acid, an inorganic alkali, or an organic alkali shown in Table 3 was added instead of water (2). The obtained coatable diffusing agent compositions were evaluated for stability over time in terms of precipitate formation during storage at 40° C. in the same manner as in Example 19. The results are shown in Table 3. Table 3 also includes the results of Example 19 and Comparative Example 2 for reference.

TABLE 3

| | | | | | | | Evaluation | |
|---|---|---|---|---|---|---|---|---|
| | | | | | | | results of storage test | |
| | | | | | | | | Time during |
| | Compositional weight (g) | | | | | Ti/P | Storage | which solution |
| | | Diphosphorus | | | | weight | temperature | remained |
| | Isopropanol | pentaoxide | Additives | | Tetraisopropoxytitanium | ratio | (° C.) | transparent (h) |
| Example 19 | 90 | 3.1 | Water | 0.15 | 5.6 | 0.70 | 40 | 960 |
| Example 23 | 90 | 3.1 | 20% aqueous phosphoric acid | 0.15 | 5.6 | 0.70 | 40 | 740 |
| Example 24 | 90 | 3.1 | 20% aqueous sulfuric acid | 0.15 | 5.6 | 0.70 | 40 | 300 |
| Example 25 | 90 | 3.1 | 20% aqueous hydrochloric | 0.15 | 5.6 | 0.70 | 40 | 300 |
| | | | acid | | | | | |
| Example 26 | 90 | 3.1 | 20% aqueous acetic acid | 0.15 | 5.6 | 0.70 | 40 | 480 |
| Example 27 | 90 | 3.1 | 20% aqueous TMAH | 0.15 | 5.6 | 0.70 | 40 | 300 |
| Example 28 | 90 | 3.1 | 20% aqueous KOH | 0.15 | 5.6 | 0.70 | 40 | 740 |
| Example 29 | 90 | 3.1 | 20% aqueous MEA | 0.15 | 5.6 | 0.70 | 40 | 480 |
| Comparative | 90 | 3.1 | — | | 5.6 | 0.70 | 40 | 240 |
| Example 2 | | | | | | | | |

In Table 3, the term “TMAH” refers to tetramethylammonium hydroxide and the term “MEA” refers to monoethanolamine.

Table 3 shows that the addition of water or an aqueous solution of an inorganic acid, an organic acid, an inorganic alkali, or an organic alkali increases the time during which the solution remains transparent, and especially water is the most effective in preventing the formation of precipitates and is particularly effective for improving solution life.

### INDUSTRIAL APPLICABILITY

The coatable diffusing agent composition according to the present invention can be suitably used in the production of solar cells and the like.

### REFERENCE SIGNS LIST

1, 15 Silicon substrate
2 Slice damage layer
3 Textured structure
4 Coatable diffusing agent composition
5, 17 Antireflection film
6, 18 n-Type diffusion layer
7, 9 Silver paste
8 Aluminum paste
10 Light-receiving surface electrode
11 BSF layer
12 Back silver electrode
13 Back aluminum electrode
14 Groove
16 Light-receiving surface n-type diffusion layer
19 p-Type diffusion layer
20 n-Type electrode
21 p-Type electrode
22 Back passivation film
100, 200 Solar cell

1. A coatable diffusing agent composition, comprising:
a titanate;
a phosphorus compound;
water; and
an organic solvent.

2. The coatable diffusing agent composition according to claim 1,
wherein the phosphorus compound is diphosphorus pentaoxide and/or a phosphate.

3. The coatable diffusing agent composition according to claim 1,
wherein the organic solvent is an alcohol.

4. The coatable diffusing agent composition according to claim 1,
wherein the water is present at a concentration of 5% by weight or less.

5. The coatable diffusing agent composition according to claim 1,
wherein the water is present at a concentration of 0.05 to 1.5% by weight.

6. The coatable diffusing agent composition according to claim 1,
wherein the composition has a weight ratio of titanium atoms to phosphorus atoms, represented by Ti/P, of 0.5 to 0.9.

7. A method for producing the coatable diffusing agent composition according to claim 1,
the method comprising mixing a titanate with a solution (A) that contains an organic solvent, a phosphorus compound, and water.

8. The method according to claim 7,
wherein the solution (A) is prepared by mixing water with a solution (B) that contains the organic solvent and the phosphorus compound.

9. The method according to claim 7,
wherein the water is pure water.

10. A solar cell, comprising
an n-type diffusion layer and an antireflection film each formed from the coatable diffusing agent composition according to claim 1.

11. A method for producing a solar cell, the method comprising:
applying the coatable diffusing agent composition according to claim 1 to a silicon substrate; and
subsequently heat treating the composition to form an n-type diffusion layer and an antireflection film on the silicon substrate.
